(19) United States
(12) Patent Application Publication
(10) Pub. No.: US 2024/0251680 A1
(43) Pub. Date: Jul. 25, 2024

(54) THERMOELECTRIC DEVICE, THERMOELECTRIC UNIT FOR THERMOELECTRIC DEVICE, AND ITS METHOD OF MAKING

(71) Applicant: City University of Hong Kong, Kowloon (HK)

(72) Inventors: Vaithinathan Karthikeyan, Kowloon (HK); James Utama Surjadi, Kowloon (HK); A.L. Roy Vellaisamy, Kowloon (HK); Yang Lu, Kowloon (HK)

(21) Appl. No.: 18/156,621

(22) Filed: Jan. 19, 2023

(51) Int. Cl. H10N 10/857; H10N 10/01; H10N 10/17; H10N 10/852

(52) U.S. Cl. CPC H10N 10/857; H10N 10/01; H10N 10/17; H10N 10/852

(57) ABSTRACT

A thermoelectric unit for a thermoelectric device. The thermoelectric unit includes an architected frame; and a thermoelectric material arrangement deposited or coated on at least part of the architected frame.

### TECHNICAL FIELD

The invention relates to a thermoelectric unit for a thermoelectric device, a method for making a thermometric unit for a thermoelectric device, and a thermoelectric device.

### BACKGROUND

Thermoelectric device can generally be used to convert heat to electrical power. Thermoelectric generator is an example thermoelectric device. It typically includes multiple compact, solid p-type and n-type thermoelectric legs and is used to convert waste heat to electricity.

Power conversion efficiency (ηₘₐₓ) of thermoelectric generator is governed by the temperature difference (δT) and the figure of merit (zT) of the thermoelectric material, as follows:

$${η}_{max} = \frac{δ T}{{T}_{Hot}} \frac{\sqrt{1 + zT} - 1}{\sqrt{1 + zT} + {T}_{Cold} / {T}_{Hot}}$$

One way to improve power conversion efficiency, according to the equation above, would be to improve the figure of merit. Indeed, existing studies have focused on enhancing the performance of thermoelectric materials by altering the material with defect and dopant to achieve a higher figure of merit. Problematically, however, improvement in material performance is not sufficient to overcome some limitations that prevent widespread use of thermoelectric generators. These limitations include, e.g., heat stagnation in the compact, solid p-type and n-type thermoelectric legs (e.g., which makes it difficult to maintain a thermal gradient for the applied heat), and inherent brittleness of the thermoelectric materials/legs (e.g., which makes assembly and/or manipulating of the thermoelectric device difficult, or causes failure).

A conflict typically exists between thermoelectric property and mechanical toughness of the thermoelectric legs. Specifically, thermoelectric legs with relatively high thermoelectric performance and material stability may be quite brittle whereas thermoelectric legs with high ductility may have relatively low figure of merit.

There is a need to provide a thermoelectric device (not limited to thermoelectric generator) and/or or a thermoelectric unit (leg) for it, with optimal thermoelectric property and mechanical toughness for one or more applications.

### SUMMARY OF THE INVENTION

In a first aspect, there is provided a thermoelectric unit for a thermoelectric device. The thermoelectric unit comprises an architected frame and a thermoelectric material arrangement arranged on, in particular deposited or coated on, at least part of the architected frame. The thermoelectric unit may be referred to as a thermoelectric leg.

Optionally, the architected frame has a lattice structure. The lattice structure may be, e.g., microlattice structure, nanolattice structure, etc.

Optionally, the lattice structure comprises a strut-based lattice structure with a plurality of interconnected struts. In some examples, one or more or all of the struts may be hollow. In some examples, one or more or all of the struts may be solid.

Optionally, the lattice structure defines a plurality of unit cells. The plurality of unit cells may be arranged in at least two layers, each of the at least two layers including multiple unit cells.

Optionally, the lattice structure comprises the following topology: face center cubic, octet-truss, body center cubic, tetradecahedron, or cuboctahedron. Other topologies are also possible in some examples.

Optionally, the architected frame is additively manufactured. For example, the architected frame may be additively manufactured using any of the following techniques: digital light processing (DLP), stereolithography (SLA), projection micro-stereolithography (PuSL), or direct ink writing (DIW).

Optionally, the architected frame is further partially carbonized (e.g., after it is additively manufactured).

Optionally, the architected frame is a partially carbonized, additively manufactured polymeric frame. The polymeric frame is made of one or more polymeric materials.

Optionally, the architected frame is made at least partly from one or more photopolymerizable materials, e.g., resin, ink, etc.

Optionally, the architected frame is made at least partly of one or more polymeric materials. Optionally, the one or more polymeric materials comprises one or more of: polyethylene glycol diacrylate (PEGDA), bisphenol A ethoxylate diacrylate, pentaerythritol triacrylate, urethane dimethacrylate, triethylene glycol dimethacrylate, 1,6-hexanediol diacrylate, bisphenol A-glycidyl methacrylate, trimethylolpropane triacrylate, acrylated epoxidized soybean oil, trimethylolpropane tris(3-mercaptopropionate), pentaerythritol tetra(3-mercaptopropionate), tris[2-(3-mercaptopropionyloxy) ethyl] isocyanurate, pentaerythritol tetrakis (3-mercaptopropionate), triallyl-1,3,5-triazine-2,4,6 (1H,3H,5H)-trione, oxybis(ethane-2,1-diyl))bis(oxy))bis(ethane-2,1-diyl)bis(2-(tosylmethyl) acrylate, ethyl 2-(tosylmethyl)acrylate, SU-8, 3,4 epoxycyclohexane)methyl 3,4 epoxycyclohexylcarboxylate, bisphenol A diglycidyl ether, and 1,4-cyclohexane dimethanol divinyl ether.

Optionally, the thermoelectric material arrangement is deposited or coated on substantially the entire architected frame.

Optionally, the thermoelectric material arrangement is made of one or more p-type thermoelectric materials. The one or more p-type thermoelectric materials may include, e.g., Sb₂Te₃, SnTe, or PbTe. Optionally, the thermoelectric material arrangement is made of a single p-type thermoelectric material. The single p-type thermoelectric materials may include, e.g., only one of Sb₂Te₃, SnTe, and PbTe.

Optionally, the thermoelectric material arrangement is made of one or more n-type thermoelectric materials. The one or more n-type thermoelectric materials may include, e.g., Bi₂Te₃, SnSe, or PbSe. Optionally, the thermoelectric material arrangement is made of a single n-type thermoelectric material. The single n-type thermoelectric materials may include, e.g., only one of Bi₂Te₃, SnSe, and PbSe.

Optionally, the thermoelectric material arrangement comprises a thermoelectric material coating made of one or more thermoelectric materials and coated on at least part of the architected frame. The thermoelectric material coating may be in the form of a thin film coating.

Optionally, the thermoelectric material coating has a thickness or an average thickness in the order of microns. In one example, the thermoelectric material coating has a thickness or average thickness of about 1 μm.

Optionally, the thermoelectric unit is constructed to define a plurality of boundary surfaces arranged to form a prism, cylinder, or other 3D shape. The cylinder may be a right cylinder. The cylinder may be a circular cylinder, an elliptic cylinder, a parabolic cylinder, a hyperbolic cylinder, an annular cylinder, etc. The prism may be a right prism. The prism may be a triangular prism, a rectangular prism, a cube, a polygonal prism, etc.

In a second aspect, there is provided a thermoelectric device comprising at least one, and preferably more than one, thermoelectric unit of the first aspect. The thermoelectric device may include multiple thermoelectric units, at least one (e.g., some or all) of which is the thermoelectric unit of the first aspect.

In a third aspect, there is provided a thermoelectric device comprising a plurality of thermoelectric units. The plurality of thermoelectric units comprises: one or more thermoelectric units of the first aspect, with the thermoelectric material arrangement being a p-type thermoelectric material arrangement; and one or more thermoelectric units of the first aspect, with the thermoelectric material arrangement being an n-type thermoelectric material arrangement. Accordingly, the plurality of thermoelectric units comprises one or more p-type thermoelectric units and one or more n-type thermoelectric units.

The plurality of thermoelectric units may be electrically connected, e.g., in series. The plurality of thermoelectric units may be thermally arranged in parallel.

Optionally, each of the p-type thermoelectric units and each of the n-type thermoelectric units have generally the same shape and/or the same size.

Optionally, each of the p-type thermoelectric units is constructed to define a plurality of boundary surfaces arranged to form a first shape with a first size, and each of the n-type thermoelectric units is constructed to define a plurality of boundary surfaces arranged to form a second shape with a second size. Optionally, the first shape and the second shape are substantially the same. Optionally, the first size and the second size are substantially the same.

Optionally, each of the p-type thermoelectric units is constructed to define a plurality of boundary surfaces arranged to form a generally rectangular prism. Optionally, each of the n-type thermoelectric units is constructed to define a plurality of boundary surfaces arranged to form a generally rectangular prism.

Optionally, each of the p-type thermoelectric units is constructed to define a plurality of boundary surfaces arranged to form a generally annular cylinder. Optionally, each of the n-type thermoelectric units is constructed to define a plurality of boundary surfaces arranged to form a generally annular cylinder.

Optionally, the plurality of thermoelectric units comprises a plurality of p-type thermoelectric units and a plurality of n-type thermoelectric units, and the p-type thermoelectric units and the n-type thermoelectric units are arranged in an alternating or interleaved manner.

Optionally, the plurality of thermoelectric units are arranged in an array, e.g., one with two or more rows and two or more columns.

Optionally, the thermoelectric device further comprises an electrical conductor arrangement electrically connecting the plurality of thermoelectric units in series. The electrical conductor arrangement may include one or more electrical conductors made of one or more metallic materials, such as aluminum, nickel, etc.

Optionally, the thermoelectric device further comprises a first electrical insulator and a second electrical insulator.

Optionally, the electrical conductor arrangement is arranged on the first electrical insulator and/or the second electrical insulator.

Optionally, the plurality of thermoelectric units are disposed between the first electrical insulator and the second electrical insulator.

Optionally, the first electrical insulator comprises a first insulator plate. Optionally, the second electrical insulator comprises a second insulator plate. The first insulator plate may be generally planar. The second insulator plate may be generally planar.

Optionally, the first electrical insulator is made of one or more ceramic materials, e.g., alumina. Optionally, the second electrical insulator is made of one or more ceramic materials, e.g., alumina.

Optionally, the thermoelectric device is a thermoelectric generator.

In a fourth aspect, there is provided a device with a heat source operable to generate heat and a thermoelectric device of the third aspect. The thermoelectric device is operably connected (e.g., thermally coupled) with the heat source to facilitate heat management (e.g., dissipation). The device may be, e.g., an electronic device. The electronic device may be wearable, portable, handheld, etc.

In a fifth aspect, there is provided a method for making a thermoelectric unit for a thermoelectric device. The method comprising forming an architected frame; and arranging, in particular depositing or coating, a thermoelectric material arrangement on at least part of the architected frame.

Optionally, forming the architected frame comprises: additively manufacturing a frame to form an additively manufactured frame or the architected frame.

Optionally, the architected frame is additively manufactured using any of the following techniques: digital light processing (DLP), stereolithography (SLA), projection micro-stereolithography (PuSL), or direct ink writing (DIW). Optionally, the architected frame is additively manufactured from one or more polymerizable material(s), e.g., one or more photopolymerizable material(s). Optionally, the (resulting) architected frame is made of one or more polymeric materials, such as polyethylene glycol diacrylate (PEGDA), bisphenol A ethoxylate diacrylate, pentaerythritol triacrylate, urethane dimethacrylate, triethylene glycol dimethacrylate, 1,6-hexanediol diacrylate, bisphenol A-glycidyl methacrylate, trimethylolpropane triacrylate, acrylated epoxidized soybean oil, trimethylolpropane tris(3-mercaptopropionate), pentaerythritol tetra(3-mercaptopropionate), tris[2-(3-mercaptopropionyloxy) ethyl] isocyanurate, pentaerythritol tetrakis (3-mercaptopropionate), triallyl-1,3,5-triazine-2,4,6 (1H,3H,5H)-trione, oxybis(ethane-2,1-diyl))bis(oxy))bis(ethane-2,1-diyl)bis(2-(tosylmethyl) acrylate, ethyl 2-(tosylmethyl)acrylate, SU-8, 3,4 epoxycyclohexane)methyl 3,4 epoxycyclohexylcarboxylate, bisphenol A diglycidyl ether, 1,4-cyclohexane dimethanol divinyl ether, etc.

Optionally, forming the architected frame further comprises: partially carbonizing the additively manufactured frame to form the architected frame. The partially carbonizing causes formation of pyrolytic carbon in/on the additively manufactured frame.

Optionally, the partially carbonizing is performed by thermal annealing or pyrolysis.

Optionally, forming the architected frame further comprises: thermally annealing the additively manufactured frame to partially carbonize it. The thermally annealing may be performed below (e.g., near) a decomposition temperature of the additively manufactured frame. In one example, the thermally annealing is performed at a first temperature for a first duration and then a second temperature for a second duration. The first temperature may be lower than the second temperature. The first duration may be shorter than the second duration.

Optionally, forming the architected frame further comprises: pyrolyzing the additively manufactured frame to partially carbonize it.

Optionally, depositing or coating the thermoelectric material arrangement on at least part of the architected frame comprises: depositing or coating the thermoelectric material arrangement on substantially the entire architected frame.

Optionally, the depositing or coating of the thermoelectric material arrangement is performed using deposition technique, e.g., physical vapor deposition technique, chemical vapor deposition technique, etc.

Optionally, the depositing or coating of the thermoelectric material arrangement is performed using thin film deposition technique, e.g., physical vapor deposition technique and chemical vapor deposition technique.

Optionally, the depositing or coating of the thermoelectric material arrangement is performed using physical vapor deposition technique, e.g., thermal evaporation, sputtering, pulsed laser deposition, etc.

Optionally, the depositing or coating of the thermoelectric material arrangement is performed using thermal evaporation. The thermal evaporation may be performed at room temperature and/or at sub-atmospheric pressure.

Optionally, the thermoelectric material arrangement is made of one or more p-type thermoelectric materials. The one or more p-type thermoelectric materials may include, e.g., Sb₂Te₃, SnTe, or PbTe. Optionally, the thermoelectric material arrangement is made of a single p-type thermoelectric material. The single p-type thermoelectric material may include, e.g., only one of Sb₂Te₃, SnTe, and PbTe.

Optionally, the thermoelectric material arrangement is made of one or more n-type thermoelectric materials. The one or more n-type thermoelectric materials may include, e.g., Bi₂Te₃, SnSe, or PbSe. Optionally, the thermoelectric material arrangement is made of a single n-type thermoelectric material. The single n-type thermoelectric materials may include, e.g., only one of Bi₂Te₃, SnSe, and PbSe.

Optionally, coating or depositing the thermoelectric material arrangement on at least part of the architected frame comprises: applying or coating a thermoelectric material coating made of one or more thermoelectric materials on at least part of the architected frame. Optionally, the thermoelectric material coating may be in the form of a thin film coating. The thermoelectric material coating may have a thickness or average thickness in the order of microns.

In a sixth aspect, there is provided a thermoelectric unit for a thermoelectric device, made directly or indirectly using the method of the fifth aspect.

In a seventh aspect, there is provided a thermoelectric device comprising at least one, and preferably more than one, thermoelectric unit of the sixth aspect. The thermoelectric device may include multiple thermoelectric units, at least one of which is the thermoelectric unit of the sixth aspect.

In an eighth aspect, there is provided a thermoelectric device comprising a plurality of thermoelectric units. The plurality of thermoelectric units comprises: one or more thermoelectric units of the sixth aspect, with the thermoelectric material arrangement being a p-type thermoelectric material arrangement; and one or more thermoelectric units of the first aspect, with the thermoelectric material arrangement being an n-type thermoelectric material arrangement. Accordingly, the plurality of thermoelectric units comprises one or more p-type thermoelectric units and one or more n-type thermoelectric units.

In a ninth aspect, there is provided a device with a heat source operable to generate heat and a thermoelectric device of the eighth aspect. The thermoelectric device is operably connected (e.g., thermally coupled) with the heat source to facilitate heat management (e.g., dissipation). The device may be, e.g., an electronic device. The electronic device may be wearable, portable, handheld, etc.

Other features and aspects of the invention will become apparent by consideration of the detailed description and accompanying drawings. Any feature(s) described herein in relation to one aspect or embodiment may be combined with any other feature(s) described herein in relation to any other aspect or embodiment as appropriate and applicable.

Terms of degree such that “generally”, “about”, “substantially”, or the like, are used, depending on context, to account for manufacture tolerance, degradation, trend, tendency, imperfect practical condition(s), etc.

Unless otherwise specified, the terms “connected”, “coupled”, “mounted” or the like, are intended to encompass both direct and indirect connection, coupling, mounting, etc.

### BRIEF DESCRIPTION OF THE DRAWINGS

Embodiments of the invention will now be described, by way of example, with reference to the accompanying drawings in which:

FIG. 1A is a schematic diagram illustrating a setup for additively manufacturing a lattice-based frame of a thermoelectric unit in one embodiment of the invention;

FIG. 1B is a schematic diagram illustrating difference between lattice-based frames with and without partial carbonization in one embodiment of the invention;

FIG. 1C is a graph showing degradation temperature of the lattice-based frame in one example;

FIG. 1D is a graph showing Fourier transform infra-red (FTIR) spectra of the lattice-based frames with and without partial carbonization;

FIG. 1E is a graph showing x-ray photoelectron spectroscopy (XPS) results of the lattice-based frames with and without partial carbonization;

FIG. 1F is a graph showing a Raman spectra of the lattice-based frames with and without partial carbonization;

FIG. 2 is a schematic diagram illustrating a setup for depositing thermoelectric material(s) onto a lattice-based frame of a thermoelectric unit in one embodiment of the invention;

FIG. 3 is a schematic diagram of a thermoelectric generator in one embodiment of the invention;

FIG. 4A is a schematic diagram of a unit cell of a thermoelectric microlattice in one embodiment of the invention;

FIG. 4B is a scanning electron microscopy (SEM) image showing a hierarchal structure of a thermoelectric microlattice in one embodiment of the invention;

FIG. 4C is a SEM image showing an enlarged view of the hierarchal structure of the thermoelectric microlattice of FIG. 4B (dotted line box);

FIG. 4D is a SEM image showing the hierarchal structure of the thermoelectric microlattice of FIG. 4C (dotted line box);

FIG. 4E is a SEM image showing the hierarchal structure of the thermoelectric microlattice of FIG. 4D (dotted line box);

FIG. 4F is a transmission electron microscopy (TEM) image showing the hierarchal structure of the thermoelectric microlattice of FIG. 4E (dotted line box);

FIG. 5A is a graph showing Seebeck coefficient and electrical conductivity of a 3D p-type Sb₂Te₃ thermoelectric unit (leg) at different temperatures in one embodiment of the invention;

FIG. 5B is a graph showing Seebeck coefficient and electrical conductivity of a 3D n-type Bi₂Te₃ thermoelectric unit (leg) at different temperatures in one embodiment of the invention;

FIG. 5C is a graph showing power factor of the 3D p-type Sb₂Te₃ thermoelectric unit (leg) and the 3D n-type Bi₂Te₃ thermoelectric unit (leg) in one embodiment of the invention;

FIG. 5D is a graph showing thermal conductivity of the 3D p-type Sb₂Te₃ thermoelectric unit (leg), the 3D n-type Bi₂Te₃ thermoelectric unit (leg), and the 3D architecture frame of the thermoelectric unit (leg) at different temperatures in one embodiment of the invention;

FIG. 5E is a graph showing figure of merit zTof the 3D p-type Sb₂Te₃ thermoelectric unit (leg), the 3D n-type Bi₂Te₃ thermoelectric unit (leg), and their average at different temperatures in one embodiment of the invention;

FIG. 5F is a graph showing maximum open-circuit voltage and specific power density of a thermoelectric generator (with respect to temperature difference) in one embodiment of the invention;

FIG. 5G is a graph showing power conversion efficiency and power density of the thermoelectric generator (with respect to heat absorbed) in one embodiment of the invention;

FIG. 6A is a graph showing stress-strain curves obtained from loading-unloading compression of the thermoelectric microlattice (at different strain levels) in one embodiment of the invention;

FIG. 6B is a graph showing stress-strain curves obtained from uniaxial compression of a thermoelectric microlattice and a polymer microlattice (without thermoelectric materials) in one embodiment of the invention;

FIG. 6C is a graph showing energy absorption (EA) and specific energy absorption (SEA) of a thermoelectric microlattice in one embodiment of the invention (labelled “(A)”) and a commercially obtained monolithic thermoelectric generator leg (labelled “(B)”) under uniaxial compression;

FIG. 7 is a series of images illustrating deformation of the thermoelectric microlattice in one embodiment of the invention under uniaxial compression;

FIG. 8 is a graph showing specific strength with respect to compressive strain for the thermoelectric microlattice in one embodiment of the invention and some existing monolithic thermoelectric generators and microlattices;

FIG. 9 is a graph showing specific energy absorption of the thermoelectric microlattice in one embodiment of the invention and some existing monolithic semiconductors, thermoelectric generators, and microlattices;

FIG. 10A is a plot showing heat transfer finite element model of a conventional solid (bulk) thermoelectric generator unit and a thermoelectric unit in one embodiment of the invention;

FIG. 10B are IR images of the conventional solid thermoelectric generator unit and the thermoelectric unit in one embodiment of the invention;

FIG. 10C are IR images of a p-type thermoelectric unit and an n-type thermoelectric unit in one embodiment of the invention;

FIG. 11 is a picture illustrating a setup including a thermoelectric generator in one embodiment of the invention connected with a power circuit;

FIG. 12 is a picture illustrating a setup including a thermoelectric generator in one embodiment of the invention connected with a power circuit;

FIG. 13 is an image of a thermoelectric generator (the one used in the setup of FIG. 11) in one embodiment of the invention;

FIG. 14 is a graph showing load test results (current vs voltage) of the thermoelectric generator in FIG. 11;

FIG. 15 is a graph showing load test results (current vs voltage) of the thermoelectric generator in FIG. 12;

FIG. 16 is a graph showing power conversion efficiency of the thermoelectric generator of FIG. 13 and existing thermoelectric generators at various temperatures;

FIG. 17A is a plot showing simulated thermal conduction distribution of polymer lattices (“core”) without thermoelectric coating, with p-type thermoelectric coating, and with n-type thermoelectric coating in one example;

FIG. 17B is a plot showing simulated thermal gradient distribution in a thermoelectric device in one example;

FIG. 17C is a plot showing simulated thermal gradient distribution in a pair of thermoelectric units (legs) in the thermoelectric device in one example;

FIG. 17D is a plot showing simulated voltage generation profile in the thermoelectric device in one example;

FIG. 17E is a plot showing simulated voltage generation profile in the pair of thermoelectric units (legs) in the thermoelectric device in one example;

FIG. 17F is a plot showing simulated voltage generation profile in the thermoelectric device in one example;

FIG. 17G is a plot showing simulated power characteristics of the thermoelectric unit (core-shell microlattice structure) at a thermal gradient of 120° C.;

FIG. 18 is a schematic illustration of a thermoelectric unit for a thermoelectric device in some embodiments of the invention; and

FIG. 19 is a flow chart illustrating a method for making a thermoelectric unit for a thermoelectric device in some embodiments of the invention.

### DETAILED DESCRIPTION

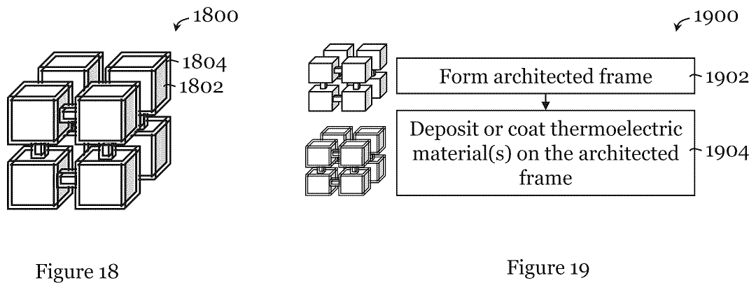

FIG. 18 shows a thermoelectric unit 1800 for a thermoelectric device in some embodiments of the invention. In some embodiments, the thermoelectric unit 1800 may be referred to as a thermoelectric leg. In some embodiments, the thermoelectric unit 1800 may be for use in a thermoelectric generator.

The thermoelectric unit 1800 has an architected frame 1802 and a thermoelectric material arrangement 1804 deposited or coated on at least part of the architected frame. In these embodiments, the architected frame 1802 is a frame that has structure other than a bulk, solid material.

The architected frame 1802 may have a lattice structure, such as a microlattice structure, a nanolattice structure, etc. The lattice structure may be a strut-based lattice structure with interconnected struts, each/some of which may be hollow or solid. The lattice structure may define multiple unit cells arranged in layers. The lattice structure may include various topology, such as face center cubic, octet-truss, body center cubic, tetradecahedron, cuboctahedron, etc. The architected frame 1802 may be additively manufactured using additively manufacturing technique, such as digital light processing (DLP), stereolithography (SLA), projection micro-stereolithography (PuSL), direct ink writing (DIW), etc. The architected frame 1802 may be made at least partly from one or more photopolymerizable materials, e.g., resin, ink, etc. The architected frame 1802 may be made at least partly of one or more polymeric materials, such as polyethylene glycol diacrylate (PEGDA), bisphenol A ethoxylate diacrylate, pentaerythritol triacrylate, urethane dimethacrylate, triethylene glycol dimethacrylate, 1,6-hexanediol diacrylate, bisphenol A-glycidyl methacrylate, trimethylolpropane triacrylate, acrylated epoxidized soybean oil, trimethylolpropane tris(3-mercaptopropionate), pentaerythritol tetra(3-mercaptopropionate), tris [2-(3-mercaptopropionyloxy) ethyl] isocyanurate, pentaerythritol tetrakis (3-mercaptopropionate), triallyl-1,3,5-triazine-2,4,6 (1H,3H,5H)-trione, oxybis(ethane-2,1-diyl))bis(oxy))bis(ethane-2,1-diyl)bis(2-(tosylmethyl) ethyl acrylate, 2-(tosylmethyl)acrylate, SU-8, 3,4 epoxycyclohexane)methyl 3,4 epoxycyclohexylcarboxylate, bisphenol A diglycidyl ether, 1,4-cyclohexane dimethanol divinyl ether, etc. The architected frame 1802 may be further partially carbonized (e.g., after it is additively manufactured). In some embodiments, the architected frame 1802 is a partially carbonized, additively manufactured polymeric frame.

The thermoelectric material arrangement 1804 may include one or more thermoelectric materials arranged on, in particular deposited or coated on, at least part of the architected frame 1802. The one or more thermoelectric materials may include one or more p-type thermoelectric materials, such as Sb₂Te₃, SnTe, PbTe, etc., and the resulting thermoelectric material arrangement may be a p-type thermoelectric material arrangement. The one or more thermoelectric materials may include one or more n-type thermoelectric materials, such as Bi₂Te₃, SnSe, PbSe, etc., and the resulting thermoelectric material arrangement may be an n-type thermoelectric material arrangement. In some embodiments in which the one or more thermoelectric materials are coated on at least part of the architected frame 1802, the thermoelectric material arrangement 1804 may include a thermoelectric material coating coated on at least part of the architected frame. The coating may be in the form of a thin film coating, with a thickness or an average thickness in the order of microns, such as about 1 μm.

The thermoelectric unit 1800, with the architected frame 1802 and the thermoelectric material arrangement 1804, may define boundary surfaces arranged to form a prism, cylinder, or other 3D shape.

The thermoelectric unit 1800 can be used in a thermoelectric device. For example, the thermoelectric device may include multiple thermoelectric units, at least one or some or all of which may be the thermoelectric units 1800. In one example, the thermoelectric device includes one or more p-type thermoelectric units (one or more units 1800 with p-type thermoelectric material arrangement) and one or more n-type thermoelectric units (one or more units 1800 with n-type thermoelectric material arrangement). The thermoelectric units may be electrically connected, e.g., in series and thermally arranged in parallel. The p-type and n-type thermoelectric units may have generally the same shape and/or size. The p-type and n-type thermoelectric units may be arranged in an interleaved manner, and/or in an array, e.g., with two or more rows and two or more columns. The thermoelectric device may further include electrical conductor arrangement (e.g., one or more electrical conductors) electrically connecting the thermoelectric units in series. The one or more electrical conductors may be made of one or more metallic materials, such as aluminum, nickel, etc. The thermoelectric device may further include a first electrical insulator (e.g., plate) and a second electrical insulator (e.g., plate). At least part of the electrical conductor arrangement may be arranged on the first and/or second electrical insulators, and the thermoelectric units may be disposed between the first and second electrical insulators. The first and/or second electrical insulators can be made of one or more ceramic materials, e.g., alumina.

The thermoelectric device may be included or incorporated in a device, such as but not necessarily an electronic device, with a heat source. The thermoelectric device may be operably connected (e.g., thermally coupled) with the heat source to facilitate heat management (e.g., dissipation) of the heat source. The device may be a wearable device, a portable device, a handheld device, etc.

FIG. 19 shows a method 1900 for making a thermoelectric unit for a thermoelectric device in some embodiments of the invention. In some embodiments, the thermoelectric unit made using the method 1900 may be the thermoelectric unit 1800.

The method 1900 generally includes, in step 1902, forming an architected frame, and in step 1904, depositing or coating a thermoelectric material arrangement on at least part of the architected frame.

In step 1902, the forming of the architected frame may include additively manufacturing a frame to form an additively manufactured frame or the architected frame. The additive manufacturing technique used in step 1902 may be, e.g., digital light processing (DLP), stereolithography (SLA), projection micro-stereolithography (PuSL), or direct ink writing (DIW). And the material used in the additive manufacturing may include one or more polymerizable material(s), e.g., one or more photopolymerizable material(s). The architected frame or additively manufactured frame may be made of one or more polymeric materials, such as polyethylene glycol diacrylate (PEGDA), bisphenol A ethoxylate diacrylate, pentaerythritol triacrylate, urethane dimethacrylate, triethylene glycol dimethacrylate, 1,6-hexanediol diacrylate, bisphenol A-glycidyl methacrylate, trimethylolpropane triacrylate, acrylated epoxidized soybean oil, trimethylolpropane tris(3-mercaptopropionate), pentaerythritol tetra(3-mercaptopropionate), tris[2-(3-mercaptopropionyloxy) ethyl] isocyanurate, pentaerythritol tetrakis (3-mercaptopropionate), triallyl-1,3,5-triazine-2,4,6 (1H,3H,5H)-trione, oxybis(ethane-2,1-diyl))bis(oxy))bis(ethane-2,1-diyl)bis(2-(tosylmethyl) acrylate, ethyl 2-(tosylmethyl)acrylate, SU-8, 3,4 epoxycyclohexane)methyl 3,4 epoxycyclohexylcarboxylate, bisphenol A diglycidyl ether, 1,4-cyclohexane dimethanol divinyl ether, etc.

In step 1902, the forming of the architected frame may include partially carbonizing the additively manufactured frame to form the architected frame. The partially carbonizing may cause formation of pyrolytic carbon in/on the additively manufactured frame. The partially carbonizing is performed by thermally annealing or pyrolyzing the additively manufactured frame to partially carbonize it. The thermally annealing may be performed below (e.g., near) a decomposition temperature of the additively manufactured frame. In one example, the thermally annealing is performed at a first temperature for a first duration and then a second temperature for a second duration. The first temperature may be lower than the second temperature. The first duration may be shorter than the second duration.

In step 1904, depositing or coating the thermoelectric material arrangement on the architected frame may include depositing or coating one or more thermoelectric materials on at least part of the architected frame. In some embodiments, the one or more thermoelectric materials are deposited or coated on the frame using thin film deposition technique, e.g., physical vapor deposition technique (e.g., thermal evaporation, sputtering, pulsed laser deposition, etc.) and chemical vapor deposition technique. In some embodiments, the depositing or coating is performed using thermal evaporation, which may be performed at room temperature and/or at sub-atmospheric pressure. The one or more thermoelectric materials may include one or more p-type thermoelectric materials, such as Sb₂Te₃, SnTe, PbTe, etc., and the resulting thermoelectric material arrangement may be a p-type thermoelectric material arrangement. The one or more thermoelectric materials may include one or more n-type thermoelectric materials, such as Bi₂Te₃, SnSe, PbSe, etc., and the resulting thermoelectric material arrangement may be an n-type thermoelectric material arrangement.

Similar to thermoelectric unit 1800, the thermoelectric unit formed using the method 1900 can be used in a thermoelectric device (e.g., thermoelectric generator).

Specific examples of the thermoelectric unit, thermoelectric device, and the method illustrated and described with reference to FIGS. 18 and 19 will now be provided. It should be noted that these specific examples are only example ways in which the thermoelectric unit, thermoelectric device, and method of the invention can be realized. That is, the invention is not limited to the following specific examples.

Inventors of the present invention have devised, through research, experiments, and trials, that architected structure such as 3D lattice structures can have precisely controlled architectures to provide enhanced load bearing capabilities (e.g. high strength at low densities), and topological optimization method can be applied to modify the mechanical properties of these structures for specific application(s) and enhance their ability to sustain relatively large thermal gradients. Inventors of the present invention have designed, among other things, a thermoelectric unit (e.g., leg) for a thermoelectric device (e.g., thermoelectric generator). The thermoelectric unit generally includes an architected frame and a thermoelectric material arrangement deposited or coated on at least part of the architected frame.

In the following examples, the architected frame has a microlattice structure and is referred to as a “core”; the thermoelectric material arrangement is in the form of a thin film coated on the microlattice structure and is referred to as a “shell”. The following embodiments of the invention provide a “core-shell” thermoelectric unit for a thermoelectric device (e.g., generator), as well as a thermoelectric device (e.g., generator) including one or more of the “core-shell” thermoelectric units. The “shell” can have one or more layers. It should be noted that the “shell” need not surround the “core” in its entirety. It should be noted that the “shell” need not be continuous or endless.

Some embodiments of the invention provides a “core-shell” thermoelectric unit with 3D microlattice structure. For example, the “core-shell” thermoelectric unit may be a p-type thermoelectric unit include a hybrid carbon core and a p-type thermoelectric shell made of p-type Sb₂Te₃. For example, the “core-shell” thermoelectric unit may be an n-type thermoelectric unit include a hybrid carbon core and an n-type thermoelectric shell made of n-type Bi₂Te₃. Some embodiments of the invention provides a thermoelectric generator including multiple such n-type and p-type “core-shell” thermoelectric units. In some of these examples, the synergetic effect between the strong, ductile architected core and low-dimensional shell is harnessed to achieve optimal toughness and power conversion efficiency for the thermoelectric units and device.

In one embodiment of the invention, a “core-shell” thermoelectric unit with lattice structure is prepared using, e.g., additive manufacturing technique and thermal evaporation technique. In this embodiment, a polymer lattice, composed of polyethylene glycol diacrylate (PEGDA) (M.W. 700), is formed layer-by-layer using digital light projection (DLP). Then, the PEGDA polymer lattice is partially carbonized by thermal annealing at 200° C. for 2 hours and then 350° C. for 4 hours in an inert environment. This forms a partially carbonized additively manufactured polymeric frame. Afterwards, thermal evaporation is used to deposit thermoelectric material(s) on the partially carbonized PEGDA microlattice to form a thermoelectric material thin film or coating. The thermoelectric material deposited may be Sb₂Te₃, Bi₂Te₃, etc., depending on application and the type of unit required (n-type or p-type). Multiple p-type thermoelectric units and n-type thermoelectric units can thus be formed.

In one embodiment of the invention, a thermoelectric generator is made using the p-type thermoelectric units and n-type thermoelectric units. The p-type thermoelectric units and n-type thermoelectric units are interconnected through low resistance aluminum electric contacts and are arranged between (e.g., encased by) two electrically-insulating alumina ceramic plates.

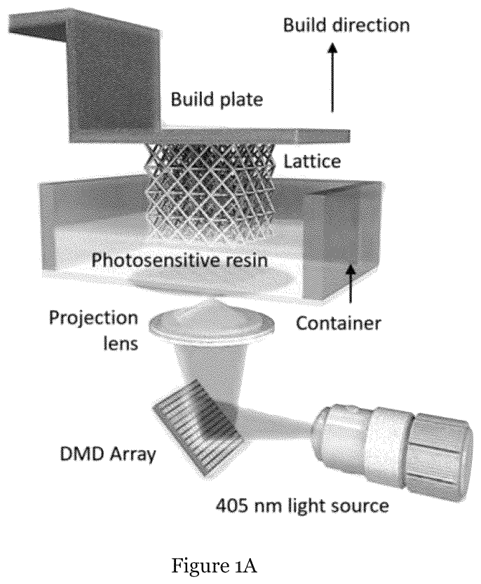

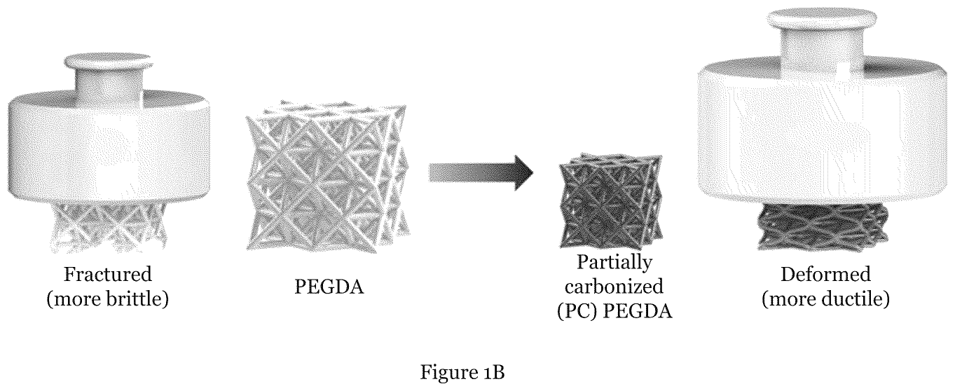

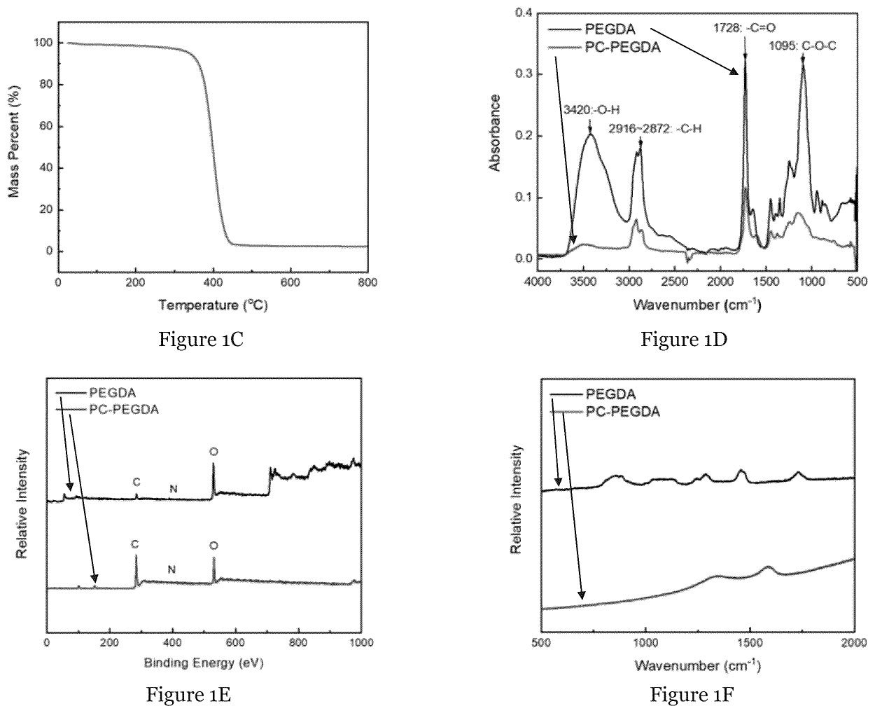

FIG. 1A shows a setup for additively manufacturing a lattice-based frame of a thermoelectric unit in one embodiment of the invention.

As shown in FIG. 1A, a polymer microlattice is formed using digital light projection technique. Digital light projection technique is a known additive manufacturing technique so will not be described in detail. Briefly, in this example, a Micromake L2 3D printer is used. Light from a light source (405 nm light source) are directed to a pool of photosensitive resin material (e.g., polyethylene glycol diacrylate (PEGDA) M.W. 700) in a container via a digital micromirror device (DMD) array and a projection lens. The light is arranged to selectively cure or solidify the photosensitive resin material while the build plate moves relatively away from the pool. This enables a lattice structure be built layer-by-layer. In this example, the polymer microlattice is a 3D core-shell thermoelectric face-centered cubic (FCC)-like microlattice, which includes diagonal struts from the edges of the cubic unit cell intersecting at the center of the cubic faces.

In one example, the slicing distance is set at 50 μm, with a curing time of 8000 ms for each 2D layer. The 3D geometry of the polymer lattice is chosen to be 4×4×4 unit cells, which serves to allow the lattice to behave as a material by minimizing edge effects. The overall size of the fabricated polymer lattice is about 10×10×10 mm³, with strut diameter of about 450 μm and slicing distance of about 50 μm. The overall size of the lattice could be modified, depending on applications. In this example, FCC structure is used to optimize the openness of the unit cells for thermoelectric material deposition and to maintain a reasonably rigid and weight-efficient geometry for structural application (owing to its stretching-dominated nature). However, in other embodiments, other topologies could also be employed, such as octet-truss, BCC, tetradecahedron, cuboctahedron, etc., depending on the required strength and thermal gradient.

In this embodiment, to enhance the high temperature thermal stability of the polymer microlattice (the additively manufactured frame), the polymer microlattice is thermally annealed near its decomposition/degradation temperature under controlled time and environment to achieve a certain (e.g., uniform) degree of carbonization throughout the lattice. In other words, the polymer microlattice is partially carbonized to produce ultra tough partially carbonized (amorphous carbon) microlattice. FIG. 1B shows the difference in mechanical properties between the polymer (PEGDA) microlattice and the partially carbonized polymer (PEGDA) microlattice. It can be seen that the partially carbonized polymer (PEGDA) microlattice is more ductile than the polymer (PEGDA) microlattice. The composition of the resulting hybrid carbon microlattice is analyzed via Fourier transform infra-red (FTIR) spectroscopy, X-ray photoelectron spectroscopy (XPS), and Raman spectroscopy. The results are shown in FIGS. 1C to 1E. Specifically, FIG. 1C is the thermogravimetric analysis (TGA) of the polymer microlattice showing a degradation temperature in the range of 300° C. to 400° C. FIG. 1D shows the Fourier Transform Infra-Red (FTIR) spectra of the polymer (PEGDA) microlattice and the partially carbonized polymer (PEGDA) microlattice. It shows the reduction of chemical bonds in the partially carbonized microlattice compared to the as-fabricated polymer microlattices. FIG. 1E shows the x-ray photoelectron spectroscopy (XPS) results. It shows the significant increase in the carbon (C) to oxygen (O) ratio in the partially carbonized microlattice. It has also been found that the intensity of polymer peaks reduces with the evidential emerging of D-band and G-band carbon peaks. FIG. 1F shows the Raman spectra of the polymer (PEGDA) microlattice and the partially carbonized polymer (PEGDA) microlattice, which verifies the formation of amorphous carbon upon partial carbonization, as shown by the D-band and G-band peaks and weakening of characteristic polymer peaks. The rise in C:O ratio observed in the XPS spectra implies the formation of pyrolytic carbon in the polymer microlattice to form a hybrid carbon composite. In one example, the PEGDA polymer lattice is annealed at 350° C. in an inert gas (e.g., N₂) environment to be partially carbonized.

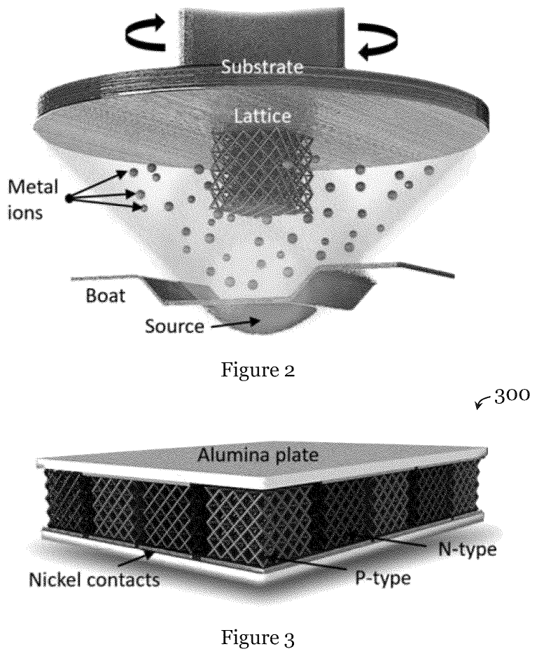

FIG. 2 shows a setup for depositing thermoelectric material(s) onto the lattice-based frame of a thermoelectric unit in one embodiment of the invention. The lattice-based frame is the one made using the above-mentioned method (additive manufacturing and partial carbonization). The setup in FIG. 2 is for performing thermal evaporation, which is a known setup hence is not described in detail. P-type thermoelectric material (in this embodiment, antimony telluride p-Sb₂Te₃) can be deposited onto the lattice-based frame to form a p-type thermoelectric unit. N-type thermoelectric material (in this embodiment, bismuth telluride n-Bi₂Te₃) can be deposited onto the lattice-based frame to form an n-type thermoelectric unit. As a result, thin film made of p-type thermoelectric material is deposited onto the partially carbonized microlattice, or thin film made of n-type thermoelectric material is deposited onto the partially carbonized microlattice, to develop core-shell thermoelectric microlattice.

Referring to FIGS. 1A and 2, the fabrication process in one embodiment is as follows. First, a polymer lattice is fabricated using a DLP 3D printer (Micromake L2) with a 405 nm light source. The photosensitive resin consists of about 98 wt % polyethylene glycol diacrylate (PEGDA) M.W. 700 and about 2 wt % phenyl bis(2,4,6-trimethyl benzoyl)phosphine oxide (BAPO) photoinitiator. The slicing distance used is 50 μm, with a curing time of 8000 ms for each 2D layer. The 3D geometry of the polymer lattice is chosen to be 4×4×4 unit cells. This serves to allow the lattice to behave as a material by minimizing edge effects. Considering experimental practicalities, FCC structure is designed in this example to optimize the openness of the unit cells for thermoelectric film deposition while maintaining a reasonably rigid and weight-efficient geometry for structural applications owing to its partially stretching dominated nature. The PEGDA polymer lattice is then partially carbonized at 350° C. for 4 hours in an inert environment. A thermoelectric film, Sb₂Te₃ film, with a thickness of about 1 μm is deposited on a partially carbonized PEGDA microlattices at room temperature by thermal evaporation of high purity (99.99%) as p-type thermoelectric unit. A thermoelectric film, Bi₂Te₃ film, with a thickness of about 1 μm is deposited on a partially carbonized PEGDA microlattices at room temperature by thermal evaporation of high purity (99.99%) as n-type thermoelectric unit. The deposition is performed at a working pressure of about 10⁻⁷ mBar and a deposition rate of about 10 Å/s for Sb₂Te₃ and about 15 Å/s for Bi₂Te₃.

In this embodiment the thermoelectric materials are deposited on the partially carbonized PEGDA microlattice at room temperature by thermal evaporation of high purity (99.99%). In this example the deposition is performed at a working pressure of about 5×10⁻⁶ Bar and at a deposition rate of about 10 Å/s and about 15 Å/s for Sb₂Te₃ and Bi₂Te₃, respectively. It should be noted that other combinations of p-type and n-type thermoelectric materials (e.g., SnTe and PbTe, SnSe and PbSe, etc.) could be deposited onto the 3D microlattice. It should also be noted that other physical vapor deposition (PVD) methods such as sputtering, pulsed laser deposition (PLD), or more generally other deposition methods, can be used. It should also be noted that other experimental conditions may also be applicable to make the n-type and p-type thermoelectric units.

FIG. 3 shows a thermoelectric generator 300 in one embodiment of the invention. The thermoelectric generator includes multiple p-type thermoelectric units (also known as legs) and multiple n-type thermoelectric units (also known as legs) arranged in an alternating or interleaved manner. The p-type thermoelectric units and n-type thermoelectric units are electrically connected in series and thermally in parallel, via nickel contacts. Two electrically insulating plates, made of alumina, are arranged on two sides of the thermoelectric units such that the thermoelectric units are disposed or secured in between. The thermoelectric units, the nickel contacts, and the electrically insulating plates are in direct or indirect material contact.

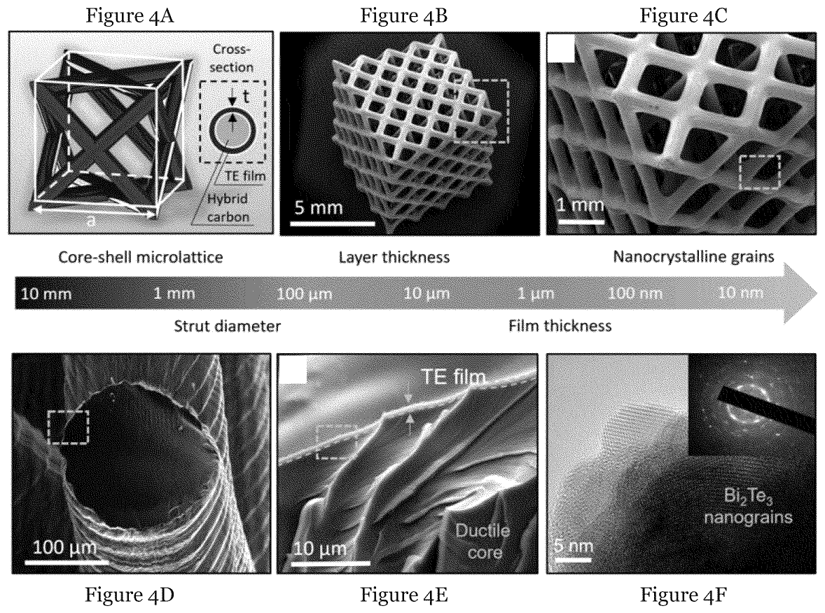

FIGS. 4A to 4F show the hierarchical structure of the thermoelectric microlattice (thermoelectric unit) made using the method of the above embodiment.

FIG. 4A shows a representative unit cell of the core-shell thermoelectric microlattice. The thermoelectric microlattice has a partially carbonized PEGDA core and a thermoelectric material film shell. The core-shell thermoelectric microlattice can be used to produce tough, ductile thermoelectric device.

FIGS. 4B to 4F show the hierarchical structure of a core-shell thermoelectric microlattice made using the method of the above embodiment. These Figures exhibit features at different scales (ranging from millimeters to nanometers). FIGS. 4B and 4C (enlarged view of the dotted line box in FIG. 4B) shows the 3D core-shell thermoelectric microlattice in this embodiment. In this embodiment, the 3D core-shell thermoelectric microlattice includes a periodic arrangement of 4×4×4 FCC-like lattice with unit cell size of about 1.25 mm. FIG. 4D (zoomed-in view of the dotted line box in FIG. 4C) shows the cross-section of the amorphous carbon beam of the 3D core-shell thermoelectric microlattice in this embodiment. The cross-section is generally circular, and the ductile carbonized core and the thermoelectric shell can be seen. FIG. 4E (zoomed-in view of the dotted line box in FIG. 4D) shows a scanning electron microscopy (SEM) image of the cross-section, which reveals a uniform deposition, with thermoelectric material film thickness of about 1 μm. FIG. 4F (zoomed-in view of the dotted line box in FIG. 4E) shows the transmission electron microscopy (TEM) image of the thermoelectric shell. As shown in FIG. 4F, the thermoelectric shell or film includes Nanograin structure, with an average grain size of about 20 nm, indicative of a nanocrystalline structure. The elemental composition and stoichiometry of the thermoelectric layer/shell on the microlattice core are analyzed via energy dispersive X-ray (EDX) mapping. The microstructures of the deposited thermoelectric shell are also investigated via X-ray diffraction (XRD), XPS, and high-resolution TEM (HRTEM). Details of these results are omitted here.

Material characterization experiments are performed. Specifically, XRD patterns of the thermoelectric thin films formed in the embodiments above are measured by grazing incidence X-ray scattering by Rigaku SmartLab diffractometer. X-ray photoelectron spectroscopy is measured to further analyze the chemical stoichiometry of the samples using XPS, PHI Model 5802. Surface morphology and elemental composition are analyzed with FESEM, FEI Quanta FEG450 with Energy Dispersive X-Ray Spectroscopy for elemental analysis and stoichiometry determination. Presence of the nanograins thermoelectric films are analyzed using Transmission Electron Microscopy (TEM, JEOL JEM 2100 F) and selected area electron diffraction are used to analyze the nanostructural properties. Further, Seebeck coefficient of the p- and n-type thermoelectric shell coated 3D microlattice are calculated from the slope of the voltage-temperature difference curve. The electrical conductivity of the thermoelectric shell coated 3D microlattice is calculated at each testing temperature by applying different current values to the sample and the resulting voltage values are measured. For calculating the electrical conductivity, the area of thermoelectric shell is calculated from known surface area of the 3D microlattice and wall thickness. Temperature dependent thermal conductivity are performed by Netzsch LFA 467 Hyperflash. The temperature dependent measurement of the electrical conductivities of p- and n-type thermoelectric films are performed through Lakeshore Hall measurement method.

Temperature-dependent thermoelectric properties of 3D microlattice architected p-type and n-type units (legs) are measured. Specifically, thermoelectric properties are measured for 1 μm thickness of p- and n-type compact and intact thermoelectric films coated on 3D microlattice scaffold.

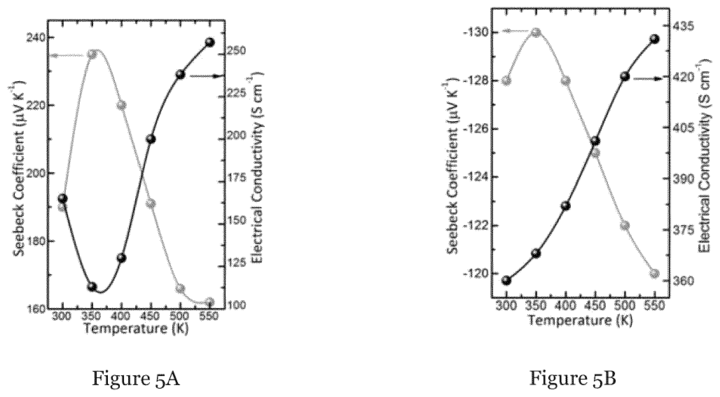

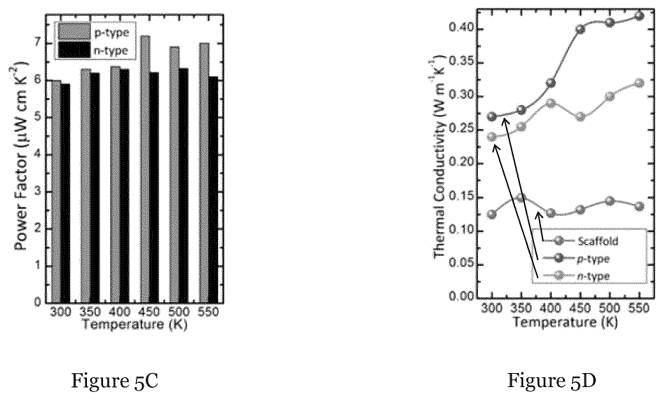

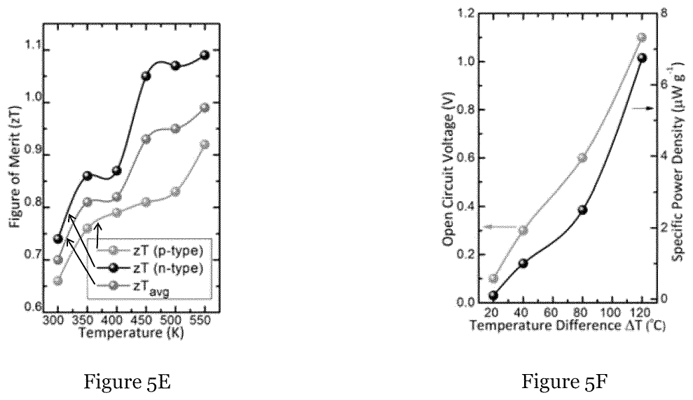

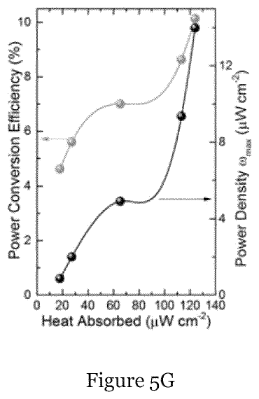

FIG. 5A shows Seebeck coefficient and electrical conductivity of a 3D p-type Sb₂Te₃ thermoelectric unit of the above embodiment at different temperatures whereas FIG. 5B is a graph showing Seebeck coefficient and electrical conductivity of a 3D n-type Bi₂Te₃ thermoelectric unit (leg) of the above embodiment at different temperatures. As shown in FIGS. 5A and 5B, the Seebeck coefficient of the 3D p-Sb₂Te₃ thermoelectric unit and the 3D n-Bi₂Te₃ thermoelectric unit ranges respectively between 160-240 μVK⁻¹ and 120-130 μVK⁻¹ in their operating temperature range. On the other hand, the electrical conductivities of the 3D structures increases with temperature following the Petritz-mobility model for 3D p-Sb₂Te₃ thermoelectric unit and 3D n-Bi₂Te₃ thermoelectric unit. The electrical conductivity ranges between 100-250 S cm⁻¹ and 360-435 S cm⁻¹, respectively.

FIG. 5C shows the power factor of the 3D p-type Sb₂Te₃ thermoelectric unit and the 3D n-type Bi₂Te₃ thermoelectric unit in one embodiment of the invention. It can be seen that the power factor remains consistent with peak values of 6.4 μW cm⁻¹K⁻² and 7 μW cm⁻¹K⁻² for 3D p-Sb₂Te₃ thermoelectric unit and 3D n-Bi₂Te₃ thermoelectric unit.

To better understand the electrical properties of the thermoelectric unit in the above embodiments, temperature dependent charge carrier concentration and mobility are determined using Hall effect measurement system for both p- and n-type thermoelectric unit samples. A synergic increase in carrier transport between the nanograins is found. This explains the increase in electrical conductivities with temperature. The charge carrier concentration for p- and n-type thermoelectric unit samples at room temperature are 1.09×10²⁰ cm⁻³ and 9.89×10¹⁹ cm⁻³ respectively.

The electrical properties of the deposited thin films are comparable with their bulk counterparts, which helps to exhibit an equivalent power factor as the bulk samples. FIG. 5D shows thermal conductivity of the 3D p-type Sb₂Te₃ thermoelectric unit, the 3D n-type Bi₂Te₃ thermoelectric unit, and the 3D architecture frame of the thermoelectric unit (the amorphous carbonized core, no thermoelectric material) at different temperatures. As shown in FIG. 5D, temperature-dependent thermal conductivity of the p- and n-type unit samples ranges between 0.23-0.45 W m⁻¹ K⁻¹ in the operating temperature region, almost an order of magnitude lower than their bulk counterparts.

As per the Callaway's model, under relaxation time approximation, the phonon relaxation time purely depends on the grain size and thickness of the thin film. Thus, in these embodiments, the thermal conductivity of thermoelectric thin films is controlled by nano-textured grains rather than the strain-induced effect in bulk materials. The temperature-dependence of the thermal conductivity must be attributed by the increased carrier transport. The partially carbonized (amorphous carbon) microlattice scaffold inherits a lower thermal conductivity, which implies that it has little contribution to the total thermal conductivity of the samples.

FIG. 5E shows figure of merit zTof the 3D p-type Sb₂Te₃ thermoelectric unit, the 3D n-type Bi₂Te₃ thermoelectric unit, and their average at different temperatures. As shown in FIG. 5E, the lower thermal conductivity and high power factor result in a larger figure of merit (zT) value of 0.97 for p-type and 1.09 for n-type at 550 K. These high zT values are made possible due to the higher temperature difference maintained by the 3D structured thermoelectric unit designs. In other words, the partially carbonized core and architecture in the units of the above embodiments help to enhance the figure of merit zT.

FIG. 5F shows the maximum open-circuit voltage and specific power density of the thermoelectric generator (with respect to temperature difference) of FIG. 3.

FIG. 5G is a graph showing power conversion efficiency and power density of the thermoelectric generator (with respect to heat absorbed) of FIG. 3.

In situ mechanical characterization of thermoelectric microlattice is performed. The experimental for in-situ uniaxial compression tests is conducted at room temperature on the MTS RT/30 electro-mechanical material testing system controlled by TestWorks 4.0 software. A high-speed video camera (Canon EOS-1D X Mark II) equipped with a telephoto macro lens (Canon EF 100-400 mm f/4.5-5.6 L IS II USM Lens with 77 mm 500D close-up lens attachment) is used to observe the deformation behavior of the lattice. Uniaxial compression tests are performed on the microlattice at a prescribed strain rate of 10⁻³ s⁻¹. Nanoindentation technique is used to measure the hardness and modulus of thermoelectric thin films by using a TI950 triboIndenter (Bruker) with a standard Berkovich tip under the displacement-controlled mode with a constant strain rate of 0.01 s⁻¹ at room temperature. The load displacement curves are recorded, and by using the nominal cross-sectional area and a total height of the lattice structures, the engineering stress and strain are calculated. The compressive strength of the polymer and thermoelectric microlattice is determined by the first applied peak load observed in the stress-strain curve before failure. The Young's Modulus are measured by fitting the linear elastic region of the stress-strain curves and energy absorption per unit volume is calculated by integration of the area under stress-strain curves.

In real-time operating environment, the applied external load on the thermoelectric module is mostly compressive in nature. Therefore, the compressive strength is a relevant parameter to evaluate the mechanical properties of thermoelectric materials. Also, improving compressive strength of the materials, e.g., through 3D cellular topological model like the above embodiments, can help to improve operational efficiency of the thermoelectric unit hence the thermoelectric device incorporating the unit.

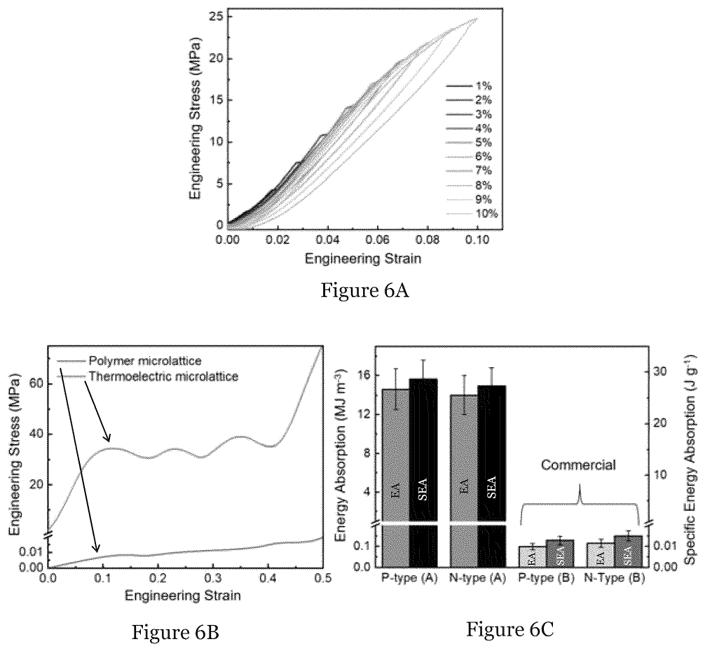

In this example, loading-unloading compression tests are performed on the microlattices. As shown in FIG. 6A, the stress-strain curves obtained from loading-unloading compression of the thermoelectric microlattice (at different strain levels) of the above embodiments, the microlattice structure exhibits nearly 100% elastic recovery up to strain levels of 10%. This result involves negligible deformation and ensures thermoelectric operation of microlattice structure even at much higher strains than the allowable strain of conventional monolithic modules. The loading-unloading compression curves of the thermoelectric microlattice in FIG. 6A show near-fully elastic behavior at strains higher than existing brittle thermoelectric generators and microlattices.

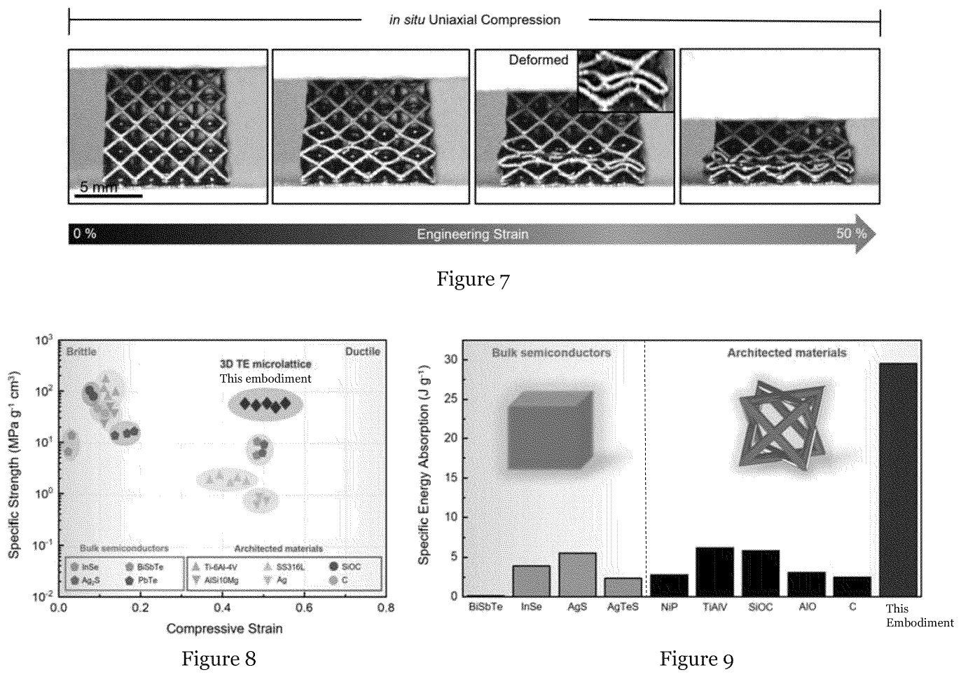

To analyze/test the mechanical properties of the thermoelectric microlattice of the above embodiments under more extreme loading conditions, in situ uniaxial compression tests of up to 50% strain are performed on the thermoelectric microlattice. FIG. 6B shows stress-strain curves obtained from uniaxial compression of the above thermoelectric microlattice embodiments and a polymer microlattice (without thermoelectric materials). FIG. 7 shows deformation of the above thermoelectric microlattice under uniaxial compression.

As shown in FIG. 6B, compared with polymer microlattice, the thermoelectric microlattice with hybrid carbon acting as its core and thermoelectric thin film as its shell exhibits significantly enhanced compressive modulus of about 450 MPa and strength of about 35 MPa This shows the drastic increase in mechanical strength (>2 orders of magnitude) of the polymer microlattice upon partial carbonization and coating with thermoelectric material film (to become the thermoelectric microlattice in the above embodiments). Also, as shown in FIG. 7, the thermoelectric microlattice exhibits localized plastic buckling without any apparent strut fracture upon yielding. The deformation behavior of the thermoelectric microlattice under uniaxial compression show its improved ductility with negligible strut fracture at high compressive strains.

FIG. 6C shows energy absorption of the thermoelectric microlattice embodiments and a commercially obtained monolithic thermoelectric generator leg under uniaxial compression. For the thermoelectric microlattice embodiments, the substantial increase in compressive strength induced by partial carbonization has made the thermoelectric composite microlattice exceed the specific strength of its commercially available bulk thermoelectric counterpart, in addition to the significantly enhanced ductility.

The suppression of strut fracture at large compressive strains (about 50%) can also be verified through the stress-strain curve, which is indicated by the absence of any large, drastic stress drops or serrations. Subsequently, a layer-by-layer deformation of the microlattice via buckling followed by densification demonstrates the characteristic of highly elastic/plastic lattices. This proves the ductility and energy absorption capabilities of the thermoelectric microlattice in these embodiments. Note that in some examples the thermoelectric microlattice has retained most of its electrical properties even after being subjected to large deformations up to 75% strain. This further demonstrates the mechanical robustness of the microlattice in these embodiments. Similar mechanical characteristics can be observed for the uncoated partially carbonized microlattices as well, with a slight decrease in specific strength and modulus. On the other hand, the pristine polymer microlattice experiences localized Euler buckling of its struts, which results in rotation and deformation at its nodes. This influence is demonstrated by the observed stress plateauing in stress-strain curve. At higher compressive strains, strut fracture occurs primarily at the nodes due to stress concentration, which is the typical location of fracture in lattices.

As result of controlled pyrolytic carbonization process, a substantial increase in compressive strength is experienced in polymer core has made the thermoelectric composite microlattice to exceed the specific strength and ductility of commercially available bulk thermoelectric counterparts. In these embodiments, this strength of the microlattice struts are derived from the formation of pyrolytic carbon including interconnected curved graphene fragments and the presence of remaining polymer chains in the hybrid composite core act as an energy dissipation matrix that restricts the brittle shear fracture of the carbon fragments, giving rise to the high ductility. Thus, the controlled carbonization of the polymer microlattices to produce hybrid carbon composite core-shell thermoelectric microlattice not only demonstrates enhanced thermal stability to withstand operating temperatures of thermoelectric generators but also increases both its strength and toughness (e.g., over 100 times).

Mechanical properties of the core-shell thermoelectric microlattice is compared against existing monolithic thermoelectric generators and architected materials. FIG. 8 shows specific strength versus compressive strain of the thermoelectric microlattice of the above embodiments compared to existing monolithic thermoelectric generators and microlattices. In this example, compressive strain is taken as either the strain at which catastrophic/brittle fracture occurs (i.e. large stress drop) for the samples in the brittle region or the maximum reported strain applied (for ductile samples). FIG. 9 shows specific energy absorption (SEA) of the thermoelectric microlattice of the above embodiments compared to existing monolithic semiconductors, thermoelectric generators, and microlattices.

From FIGS. 8 and 9, it can be seen that the thermoelectric microlattice structure of the above embodiments generally outperforms bulk thermoelectric materials and other ductile lattice structures (e.g. 316L stainless steels, Ag) in terms of its strength per unit density (i.e. specific strength) by several times while maintaining exceptional ductility. Existing micro/nanolattice with comparable specific strengths characteristically exhibit either catastrophic or brittle failure (e.g. SiOC, Ti-6Al-4V, AlSI10 Mg) at relatively low compressive strains (about 20% or lower). Unlike these existing devices, due to the high specific strength and ductile deformation behavior, the core-shell thermoelectric microlattice of the above embodiments possess higher energy absorption capability. In these embodiments, the core-shell thermoelectric microlattice can absorb more energy per unit mass (i.e., specific energy absorption) compared to existing Bi2Te3-based thermoelectric generator unit/leg (by over 102 magnitude) and existing bulk thermoelectric generator units/legs (by several times higher). This shows that the architected thermoelectric unit hence device (e.g., generator) of the present invention has optimal combination of strength and ductility with low density.

To demonstrate a thermoelectric generator with the above microlattice design structure, 10 pairs of p- and n-type microlattice structured units/legs (made based on the above embodiments) are connected in series with nickel contacts and enclosed between the insulating ceramic plates. The thermoelectric generator is shown in FIG. 3 and related prototype is shown in FIG. 13.

Experiments are performed to evaluate the performance of the device of FIG. 3 (the prototype of FIG. 13). Specifically, a Keithley 6517A Electrometer is used to measure the thermoelectric power generation (voltage) and thermal gradient across the hot and cold junction (temperature gradient across the device) using a K-type thermocouple. A FLIR E33 series infrared thermal imaging camera is used to demonstrate the temperature difference with an accuracy of up to +2° C. The temperature-dependent thermoelectric generator load characteristics (output P-V characteristics) are obtained by Keithley 6517A controlled by Labtrace 2.0 software (by sweeping the load resistance and recording the corresponding change in voltage and current from the Keithley 6517A). To demonstrate the real-time application of the 3D shape conformable thermoelectric generator, two semicircular thermoelectric generator microlattice devices are connected in series over a hot air alumina tube with temperature of 300° C. and then their corresponding power output is recorded using a multimeter. The total power conversion efficiency with respect to heat absorbed in the 3D thermoelectric microlattice device is calculated.

In this example the power conversion capacity of the constructed thermoelectric generator is analyzed and discussed in detail by calculating the heat absorbed by the 3D core-shell thermoelectric microlattice device. The electrical performance of the thermoelectric generator device is observed at the temperature difference of 20° C., 40° C., 80° ° C. and 120° C. between the hot and cold sides, respectively. Under no-load condition, the experimentally measures maximum open-circuit voltage of the thermoelectric generator is 1.1 V at ΔT of 120° C. (FIG. 5F). The maximum output power density of the microlattice thermoelectric device is calculated as about 14 μW cm⁻² (FIG. 5G). Specific power density (i.e., power to mass ratio) for the thermoelectric generator is calculated as about 7 μW g⁻¹, which is in good comparison to the conventional bulk Bi₂Te₃ thermoelectric generator device. These excellent electrical properties and the ability of the thermoelectric generator to maintain a larger temperature difference adds up to a total device efficiency of about 10% (FIG. 5G).

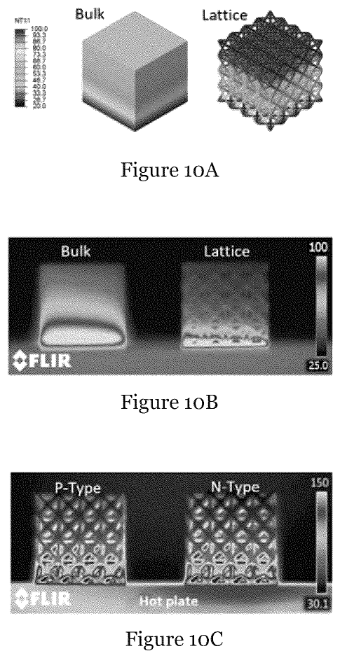

FIG. 10A shows the heat transfer finite element model of a conventional solid thermoelectric generator unit and a thermoelectric (microlattice) unit in one embodiment of the invention. FIG. 10B shows the corresponding IR images. FIG. 10A shows the reduced effective thermal conductivity of the microlattice unit embodiment compared to some existing monolithic units/legs. FIGS. 10A and 10B demonstrate the capability of the microlattice structure in this embodiment to naturally maintain a significantly larger temperature difference between hot and cold sides (compared to its bulk counterpart).

The slight difference in thermal conductivity between the p- and n-type thermoelectric generator (microlattice) units are also verified through IR imaging. FIG. 10C show IR images of the p-type thermoelectric (microlattice) unit embodiment and the n-type thermoelectric (microlattice) unit embodiment. It can be seen that the n-type thermoelectric (microlattice) unit embodiment exhibits a slightly higher thermal gradient than the p-type thermoelectric (microlattice) unit embodiment due to its lower thermal conductivity.

In FIGS. 10B and 10C, the hotter areas in the infra-red images are attributed to the difference in thermal conductivity of the samples. For instance, in FIG. 10B, the bulk material conducts heat slower than the microlattice sample, thus gives rise to hotter area near the bottom surface of the bulk sample. For instance, in FIG. 10C, the thermal conductivity of the n-type thermoelectric material is lower than that of the p-type material, which results in the area near the bottom surface of the n-type thermoelectric microlattice being hotter than the area at the bottom of the p-type sample.

The real-time performance of the thermoelectric generator in this embodiment under load condition with varied temperature differences is investigated in detail.

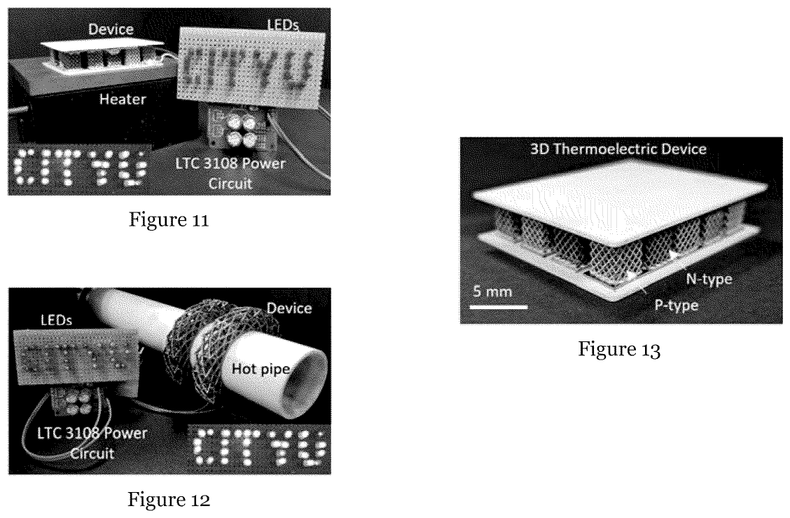

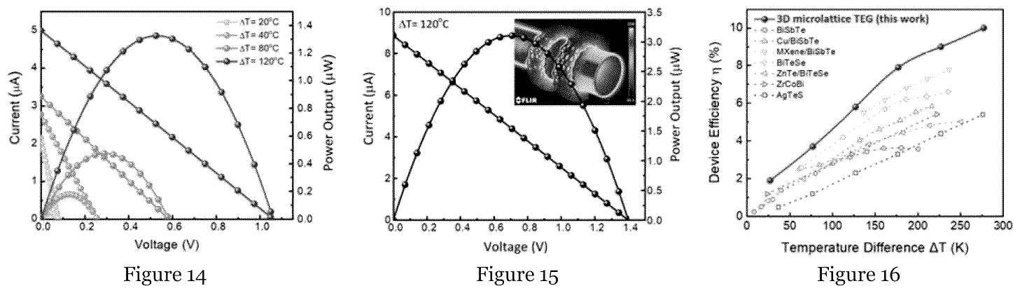

FIG. 11 shows a setup illustrating the thermoelectric generator in one embodiment connected with a power circuit (LTC3108 power circuit) with multiple LEDs. The thermoelectric generator is the generator in FIG. 13 designed based on the generator of FIG. 3. As shown in FIG. 11, in this example, the thermoelectric generator in this embodiment is placed over a resistive heat source, and temperature difference is monitored using a K-type thermocouple. The cold side of the thermoelectric generator is naturally cooled by atmospheric airflow instead of using forced heat transfer mechanisms such as water-cooled or heat sinks. The load test at specified ΔT is conducted using variable resistive loads; the output characteristics of microlattice based thermoelectric generator is shown in FIG. 14, where the maximum power output of about 1.4 μW. The obtained maximum power output of the thermoelectric generator is in good agreement with its calculated specific power density.

To demonstrate a conformable 3D structural design to the specific shape of heat source, an annular thermoelectric generator is constructed based on the above design principles and studied. FIG. 12 shows another illustrating a thermoelectric generator in one embodiment of the invention connected with a power circuit. This thermoelectric generator is different from the generator in FIG. 13. The annular thermoelectric generator design conforms to tubular heat sources like chimneys and vehicle exhausts. The annular-cylinder 3D printed thermoelectric structure is mounted on an alumina pipe with a hot air exhaust outlet of 150° C., as shown in FIG. 12. Temperature difference of 120° C. is maintained between the circular 3D thermoelectric structures to conduct the load test, which exhibited a maximum power output of 3.2 μW as shown in FIG. 15.

The maximum power point in each of the thermoelectric generators in FIGS. 11 and 12 is tracked and stored in a LTC3108 power circuit. The thermoelectric generators in FIGS. 11 and 12 can light up the LEDs in the LTC3108 power circuit, as shown in the inset of FIGS. 11 and 12.

Throughout the experiments in FIGS. 11 and 12, the cold side of the thermoelectric generator is found to remain at room temperature. This demonstrates the ability of the thermoelectric generator to practically maintain significant thermal gradient and power output.

The power conversion efficiency of the architected thermoelectric generator used in FIG. 11 (the thermoelectric generator of FIG. 13) is compared with existing thermoelectric generators. FIG. 16 shows the comparison results. Due to the reduced thermal conductivity caused by the synergy between the open cellular architecture and quantum confinement effect due to the reduced dimensions, the device efficiency of the thermoelectric generator of FIG. 13 surpasses all other thermoelectric generators compared. It is expected that with this level of device efficiency, thermoelectric power conversion technology can stand comparable with other renewable energy technologies.

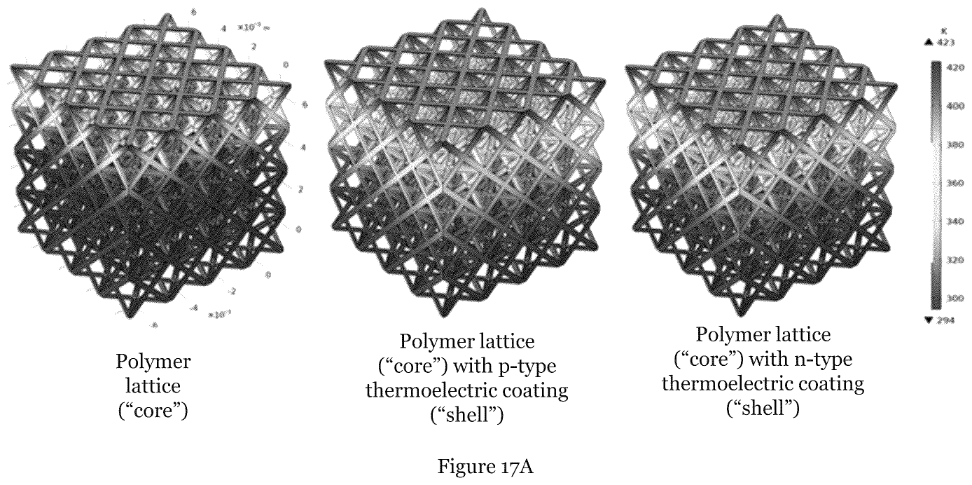

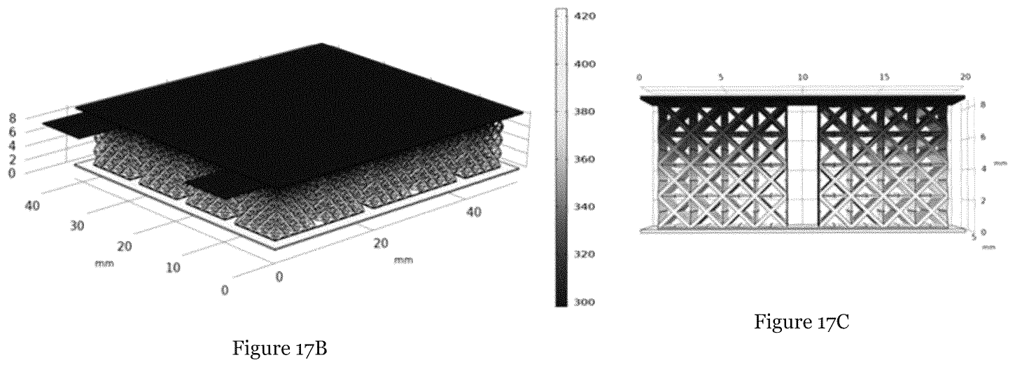

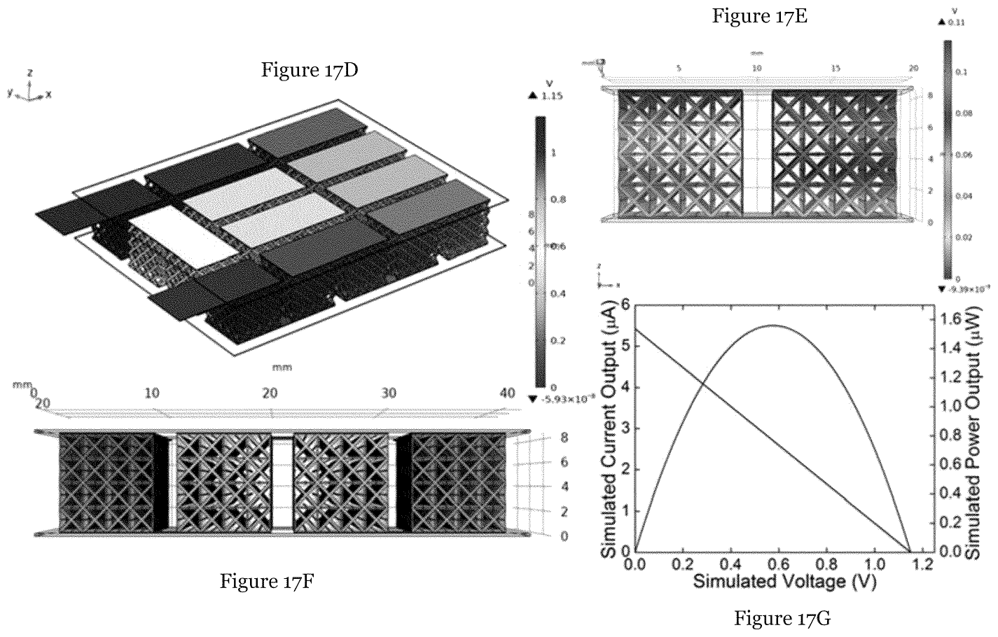

A finite element study is performed using COMSOL Multiphysics® software for the 3D architected thermoelectric units and associated thermoelectric generators. The model calculates the thermal gradient profile of the thermoelectric units (core-shell thermoelectric microlattice structures) and the thermoelectric device with multiple thermoelectric units disposed between a pair of generally planar, flat alumina plates. During the simulation, the cold side and the ambient air was maintained at 25° ° C., with natural convective heat transfer coefficient of air as 10 W m2 K⁻¹. On the basis of mirolattice geometry and material properties the internal electrical resistance was estimated as 0.2 kΩ per thermoelectric pair at room temperature. The device geometry is the same as the experimented thermoelectric module (FIG. 13) dimensions, with 10 thermoelectric leg pairs and a height of 8 mm. Simulation for analyzing the difference in thermal conduction with and without thermoelectric shell coating over the polymer core is performed. The results are shown in FIG. 17A, which demonstrate a negligible parasitic heat transfer between the polymer microlattice core and thermoelectric coating (shell). FIGS. 17B and 17C demonstrate the thermal gradient distribution of the device and a pair of thermoelectric units of the device respectively, over the device at a thermal gradient ΔT of 120° C. FIGS. 17D to 17F show simulated thermoelectric voltage distribution profile of the device and the pair of thermoelectric units of the device. FIG. 17G shows the power generation results at a temperature gradient of 120° C. The results of the simulation support the experimental results. In particular, the simulated thermal distribution and the voltage generation from the 3D thermoelectric core-shell microlattice device demonstrates a larger thermal gradient at higher operating temperature range. Also, the simulated power output characteristics validates the experimental results and demonstrates a maximum power output of 1.5 μW at a thermal gradient ΔT of 120° C.

The above disclosure has provided a strategy to sustain large thermal gradient in thermoelectric generator and potentially suppress the inherent brittleness. Some embodiments of the invention provide a thermoelectric unit with a core-shell microlattice configuration, which combines partially carbonized composite 3D architectures with thermoelectric materials deposits (e.g., thin films). Some embodiments of the invention provide a thermoelectric generator with microlattice geometry that could be made to conform to different heat radiating surfaces, with improved, optimal mechanical toughness and power conversion efficiency. The 3D thermoelectric microlattice architecture in some embodiments of the invention can facilitate larger electrical conductivity and ultra-low thermal conductivity in the thermoelectric device, which results in improved power conversion efficiency. Furthermore, in some embodiments of the invention, the enhanced toughness is attributed to the carbon composite core which possess strength multi-fold higher than existing bulk thermoelectric materials and engineering alloys such as stainless steels, as well as improved fracture resistance that can resist more than 10 times deformation than its pure monolithic thermoelectric counterpart (Bismuth Telluride-based alloys). It is envisaged that the thermoelectric units and thermoelectric devices (generators, for example) of the invention can facilitate widespread use of thermoelectric devices and can facilitate macro- to microscale process ability for multi-scale waste heat recovery and wearable applications.

Some embodiments of the invention have provided a three-dimensional (3D) architected thermoelectric generator with thermoelectric units having microlattice structures fabricated through additive manufacturing (AM) and thin film deposition techniques (e.g. thermal evaporation, sputtering). The thermoelectric generator or device in some embodiments of the invention can be used for multiscale waste heat recovery applications, e.g., in microprocessors, electronic devices, space machines, etc.

In some embodiments, the 3D microlattice of the thermoelectric unit could be fabricated via digital light processing (DLP), stereolithography (SLA), projection micro-stereolithography (PuSL), or direct ink writing (DIW), e.g., using a photopolymerizable resin/ink followed by one or more post-processing techniques, such as thermal annealing, pyrolysis, etc., and further followed by material deposition (e.g., thin film deposition). This approach can decrease the thermal impedance as well as improve the temperature gradient, thereby increasing the power conversion efficiency of the thermoelectric unit or the thermoelectric deice incorporating such thermoelectric unit(s). In some embodiments, the additively manufactured unit have a lightweight architecture that exhibits higher specific strength than conventional bulk thermoelectric materials and that has improved ductility hence toughness. The design of the units and the devices in some embodiments are readily scalable and shape conformable. As a result, the units and the devices can be used or applied in a wide range of applications from low-grade human body heat harvesting to industrial grade waste heat recovery.

Some embodiments of the invention have provided a thermoelectric generator. The thermoelectric generator may have one or more of the following example features. For example, the thermoelectric generator can maintain larger thermal gradient and can be used for continuous power generation from the body heat or any low grade heat source. For example, the thermoelectric generator has relative high specific energy absorption and relative high specific mechanical strength, which allows it be placed in areas where other devices or generators could not be employed due to their low strength and brittle nature. For example, the thermoelectric generator can be scaled-up for large scale energy harvesting in heavy industries and other renewable energy sectors. For example, the thermoelectric generator can be used as heat sinks in thermal management unit. Some embodiments of the invention have provided a thermoelectric unit with an additive manufactured microlattice structure and for a thermoelectric device (e.g., generator). The thermoelectric unit or the thermoelectric device can be used in wearable electronics (e.g., self-powering electronic devices) and thermal management devices.

It will be appreciated by persons skilled in the art that numerous variations and/or modifications may be made to the invention as shown in the specific embodiments to provide other embodiments of the invention. The described embodiments of the invention should therefore be considered in all respects as illustrative, not restrictive. Example optional features of some aspects of the invention are set forth in the summary section. Some embodiments of the invention may include one or more of these optional features (some of which are not specifically illustrated in the drawings). Some embodiments of the invention may lack one or more of these optional features (some of which are not specifically illustrated in the drawings). For example, the architected frame of the thermoelectric unit may not have a microlattice structure, but have other structure such as lattice (nanolattice) structure. For example, the architected frame can be manufactured using different additive manufacturing techniques. For example, the architected frame can be manufactured using non additive manufacturing technique (e.g. molding). For example, the architected frame can additionally or alternatively be made with polymeric material(s) other than PEGDA. For example, the thermoelectric material arrangement of the thermoelectric unit may be a p-type thermoelectric material arrangement or an n-type thermoelectric material arrangement. For example, the thermoelectric material arrangement may be arranged on the frame using various methods not limited to vapour deposition. The thermoelectric material arrangement may or may not be in the form of a thin film or like coating. One of more of the size, shape, configuration, etc., of thermoelectric unit can be different from those illustrated. One of more of the size, shape, configuration, etc., of thermoelectric device can be different from those illustrated. The thermoelectric device can have any number of thermoelectric units (one or more or all are the thermoelectric units of the invention). The thermoelectric device can have various different applications including but not limited to those specifically illustrated.

1. A thermoelectric unit for a thermoelectric device, comprising:
an architected frame; and
a thermoelectric material arrangement deposited or coated on at least part of the architected frame.

2. The thermoelectric unit of claim 1, wherein the architected frame has a lattice structure.

3. The thermoelectric unit of claim 2, wherein the lattice structure comprises a strut-based lattice structure with a plurality of interconnected struts.

4. The thermoelectric unit of claim 2, wherein the lattice structure comprises a microlattice structure.

5. The thermoelectric unit of claim 2, wherein the lattice structure comprises a nanolattice structure.

6. The thermoelectric unit of claim 2, wherein the lattice structure comprises the following topology: face center cubic, octet-truss, body center cubic, tetradecahedron, or cuboctahedron.

7. The thermoelectric unit of claim 1, wherein the architected frame is additively manufactured.

8. The thermoelectric unit of claim 7, wherein the architected frame is further partially carbonized.

9. The thermoelectric unit of claim 1, wherein the architected frame is a partially carbonized, additively manufactured polymeric frame.

10. The thermoelectric unit of claim 1, wherein the architected frame is made at least partly of one or more polymeric materials.

11. The thermoelectric unit of claim 1, wherein the thermoelectric material arrangement is deposited or coated on substantially the entire architected frame.

12. The thermoelectric unit of claim 1, wherein the thermoelectric material arrangement is made of one or more p-type thermoelectric materials.

13. The thermoelectric unit of claim 12, wherein the one or more p-type thermoelectric materials comprises at least one of: Sb₂Te₃, SnTe, and PbTe.

14. The thermoelectric unit of claim 1, wherein the thermoelectric material arrangement is made of one or more n-type thermoelectric materials.

15. The thermoelectric unit of claim 14, wherein the one or more n-type thermoelectric materials comprises at least one of: Bi₂Te₃, SnSe, and PbSe.

16. The thermoelectric unit of claim 1, wherein the thermoelectric material arrangement comprises a thermoelectric material coating made of one or more thermoelectric materials and coated on at least part of the architected frame.

17. The thermoelectric unit of claim 16, wherein the thermoelectric material coating has a thickness or an average thickness in the order of microns.

18. A thermoelectric device comprising at least one thermoelectric unit of claim 1.

19. A thermoelectric device comprising a plurality of thermoelectric units, the plurality of thermoelectric units including:
one or more thermoelectric units comprising:
an architected frame; and
a thermoelectric material arrangement deposited or coated on at least part of the architected frame, wherein the thermoelectric material arrangement is made of one or more p-type thermoelectric materials, each operable as a p-type thermoelectric unit; and
one or more thermoelectric units of claim 14, each operable as an n-type thermoelectric unit.

20. The thermoelectric device of claim 19,
wherein each of the p-type thermoelectric units is constructed to define a plurality of boundary surfaces arranged to form a first shape with a first size; and
wherein each of the n-type thermoelectric units is constructed to define a plurality of boundary surfaces arranged to form a second shape with a second size.

21. The thermoelectric device of claim 20,
wherein the first shape and the second shape are substantially the same; and/or
wherein the first size and the second size are substantially the same.

22. The thermoelectric device of claim 19,
wherein the plurality of thermoelectric units comprises a plurality of p-type thermoelectric units and a plurality of n-type thermoelectric units; and
wherein the p-type thermoelectric units and the n-type thermoelectric units are arranged in an alternating or interleaved manner.

23. The thermoelectric device of claim 19, wherein the thermoelectric device is a thermoelectric generator.

24. A method for making a thermoelectric unit for a thermoelectric device, the method comprising:
forming an architected frame; and
depositing or coating a thermoelectric material arrangement on at least part of the architected frame.

25. The method of claim 24, wherein forming the architected frame comprises:
additively manufacturing a frame to form an additively manufactured frame or the architected frame.

26. The method of claim 25, wherein the architected frame is additively manufactured using one of the following techniques: digital light processing (DLP), stereolithography (SLA), projection micro-stereolithography (PuSL), and direct ink writing (DIW).

27. The method of claim 25, wherein forming the architected frame further comprises:
partially carbonizing the additively manufactured frame to form the architected frame.

28. The method of claim 27, wherein the additively manufactured frame is partially carbonized by thermal annealing or pyrolysis.

29. The method of claim 24, wherein depositing or coating the thermoelectric material arrangement on at least part of the architected frame comprises:
depositing or coating the thermoelectric material arrangement on substantially the entire architected frame.

30. The method of claim 29, wherein the depositing or coating of the thermoelectric material arrangement is performed using thin-film deposition technique.

31. The method of claim 29, wherein the thermoelectric material arrangement is made of one or more p-type thermoelectric materials.

32. The method of claim 29, wherein the thermoelectric material arrangement is made of one or more n-type thermoelectric materials.
